(19) United States
(12) Patent Application Publication
(10) Pub. No.: US 2026/0150535 A1
(43) Pub. Date: May 28, 2026

(54) DISPLAY DEVICE

(71) Applicant: LG Display Co., Ltd., Seoul (KR)

(72) Inventors: Dongkyu LEE, Paju-si (KR); Jungho BANG, Paju-si (KR); Kyu-Hwang LEE, Paju-si (KR); Munchan KANG, Paju-si (KR)

(73) Assignee: LG Display Co., Ltd., Seoul (KR)

(21) Appl. No.: 19/329,113

(22) Filed: Sep. 15, 2025

(30) Foreign Application Priority Data
Nov. 28, 2024 (KR) 10-2024-0174031

(51) Int. Cl. H10K 59/131; H10K 59/124; H10K 59/40; H10K 102/00

(52) U.S. Cl. CPC H10K 59/131; H10K 59/124; H10K 59/40; H10K 2102/311

(57) ABSTRACT

A display device according to embodiments of the present specification includes a substrate including a display area and a bending area, a connection line crossing the bending area of the substrate, a planarization layer covering the connection line in the bending area, a stress relief layer disposed on the planarization layer in the bending area, and a metal grid pattern disposed on the connection line in the bending area, in which a groove is disposed in an upper surface of the stress relief layer, and the metal grid pattern is disposed to correspond to the groove.

### CROSS-REFERENCE TO RELATED APPLICATION

The present application claims priority to Korean Patent Application No. 10-2024-0174031, filed November 28, 2024, the entire contents of which is incorporated herein for all purposes by this reference.

### BACKGROUND

### Technical Field

Display devices are applied to various electronic devices such as TVs, mobile phones, notebooks, tablets, etc.

### Description of the Related Art

Examples of display devices include organic light-emitting diode (OLED) display devices that emit light by itself, liquid crystal display (LCD) devices that require a separate light source, etc.

A bezel area of the display device is a factor that reduces aesthetics and immersion by being recognized by a user. Recently, narrow bezel display devices that reduce the bezel area in which an image of the display device is not displayed are in the spotlight.

### BRIEF SUMMARY

Research is being conducted to reduce a bezel area of a display device recognized by a user by bending a non-display area of a display panel using a flexible substrate and hiding a part of the non-display area on a back surface of a display area. Connection lines for electrically connecting the display area to a pad area can be disposed in a bending area of the display panel, and organic materials covering the connection lines can be disposed.

Due to a curvature of the bending area of the display panel, a tensile stress can be applied to the organic materials and the connection lines in the bending area, and thus cracks can occur in the organic materials and connection lines in the bending area. Cracks occurring in the organic materials positioned on an upper portion of the bending area in which a relatively large tensile stress is applied can propagate to the connection lines, causing cracks in the connection lines.

The object to the present specification is to provide a display device in which a tensile stress applied to an organic material layer in a bending area can be efficiently distributed when a display panel is bent and cracks can be prevented from occurring in the organic material layer.

The object to the present specification is also to provide a display device in which a curvature of a bending area of a display panel can be further reduced, thereby further reducing a lower bezel area of the display panel.

The object to the present specification is also to provide a display device in which production energy required for production can be reduced and greenhouse gas emissions can be reduced.

Objects of the present specification are not limited to the above-described objects, and other objects that are not mentioned will be able to be clearly understood by those skilled in the art based on the following description.

According to embodiments of the present specification, there is provided a display device including a substrate including a display area and a bending area, a connection line crossing the bending area of the substrate, a planarization layer covering the connection line in the bending area, a stress relief layer disposed on the planarization layer in the bending area, and a metal grid pattern disposed on the connection line in the bending area, in which a groove is disposed in an upper surface of the stress relief layer, and the metal grid pattern is disposed to correspond to the groove.

According to embodiments of the present specification, there is provided a display device including a substrate including a display area and a bending area, a first organic material layer disposed in the bending area of the substrate, a connection line crossing the bending area of the substrate and disposed on the first organic material layer, a second organic material layer covering the connection line in the bending area, a third organic material layer disposed on the second organic material layer in the bending area, and a metal grid pattern disposed on the connection line in the bending area, in which a groove is disposed in an upper surface of the third organic material layer, and the metal grid pattern is disposed to correspond to the groove.

According to the display device according to the embodiments of the present specification, by including the metal grid pattern embedded in the organic material layer disposed on the connection line in the bending area, it is possible to efficiently distribute the tensile stress applied to the organic material layer when the bending area of the display device is bent. Accordingly, cracks can be prevented from occurring in the organic material layer when the bending area of the display device is bent, and cracks in the organic material layer can be prevented from propagating and causing cracks in the connection lines.

In addition, in the display device according to the embodiments of the present specification, the tensile stress applied to the organic material layer when the bending area of the display device is bent can be distributed, the curvature of the bending area can be further reduced. Accordingly, the lower bezel area of the display device according to the embodiments of the present specification can be further reduced.

In addition, in the display device according to the embodiments of the present specification, since the tensile stress applied to the organic material layer when the bending area of the display device is bent can be distributed, the resin layer previously additionally coated on the bending area in order to reduce the tensile stress by adjusting a position of a neutral surface of the bending area can be omitted.

According to the embodiments of the present specification, the production energy required for producing the display device can be reduced due to the low defect rate of the display device caused by the cracks of the bending area, and greenhouse gas emissions can be reduced.

Effects of the present specification are not limited to the above-described effects, and other effects that are not mentioned will be able to be clearly understood by those skilled in the art based on the following detailed description.

### BRIEF DESCRIPTION OF THE SEVERAL VIEWS OF THE DRAWINGS

FIG. 1 is a plan view of a display device according to one embodiment of the present specification.

FIG. 2 is a cross-sectional view of the display device along line II-II in FIG. 1.

FIG. 3 is an enlarged view of area III in FIG. 1.

FIG. 4 is a cross-sectional view of the display device along line IV-IV in FIG. 3.

FIGS. 5A to 5C are cross-sectional views showing a method of manufacturing a metal grid pattern according to one embodiment of the present specification.

FIG. 6 is a plan view showing a bending area of the display device according to one embodiment of the present specification.

FIG. 7 is a cross-sectional view of the display device along line VII-VII in FIG. 6.

FIGS. 8A to 8C are cross-sectional views showing a method of manufacturing a metal grid pattern according to one embodiment of the present specification.

FIG. 9 is a plan view showing a metal grid pattern of the display device according to one embodiment of the present specification.

FIG. 10 is a plan view showing a metal grid pattern of the display device according to one embodiment of the present specification.

### DETAILED DESCRIPTION

Advantages and features of the present specification and methods for achieving them will become clear by referencing embodiments described below in detail in conjunction with the accompanying drawings. However, the present specification is not limited to the embodiments disclosed below but will be implemented in various different forms, these embodiments are merely provided to make the disclosure of the present specification complete and fully inform those skilled in the art to which the present specification pertains of the scope of the present specification.

Since shapes, sizes, ratios, angles, numbers, etc., disclosed in the drawings for describing the embodiments of the present specification are illustrative, the present specification is not limited to the shown items. The same reference number denotes the same components throughout the specification. In addition, in describing the present specification, when it is determined that the detailed description of a related known technology may unnecessarily obscure the gist of the present specification, the detailed description thereof will be omitted. When “comprise,” “have,” “consist of,” or the like described herein are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, one or more other parts may be positioned between the two parts, for example, unless “immediately,” “directly,” or “close to” is used.

When the temporal relationship is described, when the temporal relationship is described using “after,” “subsequently,” “then,” “before,” or the like, it may also include a non-consecutive case unless “immediately” or “directly” is used.

Although terms such as first and second are used to describe various components, these components are not limited by these terms. These terms are only used to distinguish one component from another component. Therefore, a first component described below may be a second component within the technical spirit of the present specification.

In the description of components of the present specification, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between components that may be connected, coupled, joined, or attached indirectly unless otherwise stated specially.

When a component or a layer is described as “coming into contact with” or “overlapping” another component or layer, the component or the layer may come into direct contact with or directly overlap another component or layer, but it should be understood that still another component may be interposed between components that may come into indirect contact with and indirectly overlap each other unless otherwise stated specially.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present specification may act functionally.

Features of various embodiments of the present specification may be coupled or combined partially or entirely, various technological interworking and driving are made possible, and the embodiments may be implemented independently of each other or implemented together in an associated relationship.

Hereinafter, various embodiments of the present specification will be described in detail with reference to the accompanying drawings.

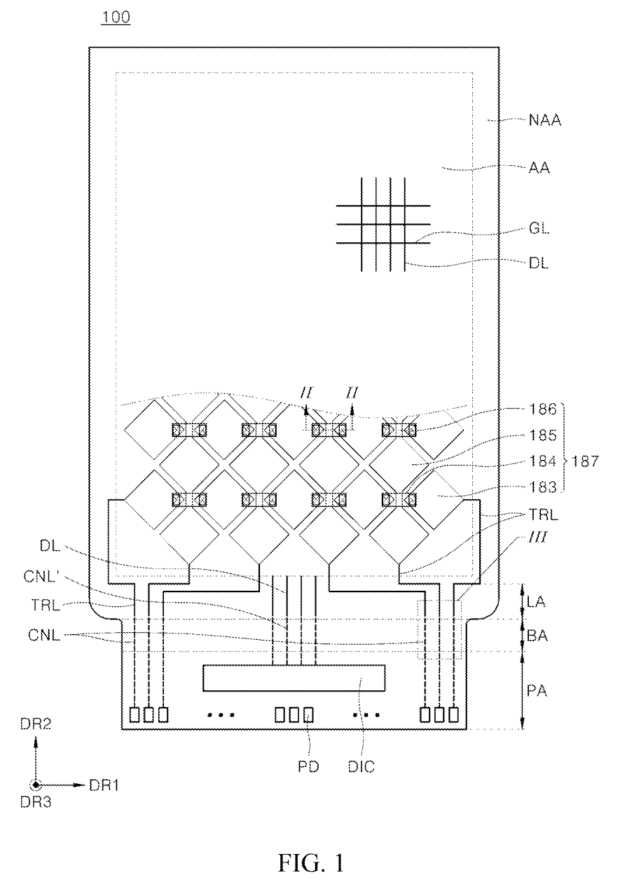

FIG. 1 is a plan view of a display device according to one embodiment of the present specification.

Referring to FIG. 1, a display device according to one embodiment of the present specification may include a display panel 100, a data driver DIC, a flexible printed circuit board, a timing controller, a power supplier, etc.

The display panel 100 may include a display area AA and a non-display area NAA. The display area AA and the non-display area NAA may be areas of a substrate. The display area AA is an area in which an image is displayed. The non-display area NAA is an area in which an image is not displayed and which is positioned outside the display area AA.

The display area AA is an area in which a plurality of pixels are arranged. Each pixel may include a plurality of sub-pixels. The non-display area NAA is an area in which a gate driver, various link lines, various power supply lines, etc., are disposed.

The display area AA includes a plurality of data lines DL and a plurality of gate lines GL that are disposed to intersect each other. The plurality of gate lines GL may extend, for example, in a first direction DR1, and the plurality of data lines DL may extend, for example, in a second direction DR2. The data line DL transmits a data signal generated by the data driver DIC to the sub-pixel, and the gate line GL transmits gate signals generated by the gate driver to the sub-pixel.

The gate driver may be disposed, for example, in the non-display area NAA positioned at left and right sides of the display area AA. The gate driver may be disposed directly on the substrate of the display panel 100 in a gate driver in panel (GIP) type.

The non-display area NAA may be disposed to surround the display area AA. For example, when the display area AA has a quadrangular shape, the non-display area NAA may be disposed at upper, lower, left, and right sides of the display area AA. The non-display area NAA positioned below the display area AA includes a pad area PA in which the data driver DIC and a flexible printed circuit board are bonded, a link area LA and a bending area BA that are defined between the link area LA and the pad area PA.

The data driver DIC and the flexible printed circuit board may be bonded to the pad area PA by an anisotropic conductive film. The flexible printed circuit board may be bonded to pads PD disposed on an end portion of the pad area PA. The timing controller and the power supplier may be mounted on the flexible printed circuit board.

A part of the non-display area NAA of the display panel 100 may be bent at a predetermined curvature. A bent area of the non-display area NAA of the display panel 100 may be defined as the bending area BA.

As the bending area BA of the display panel 100 is bent, the pad area PA of the non-display area NAA may be positioned to overlap the display area AA on a back surface of the display area AA. Accordingly, the lower bezel area of the display device recognized from a front surface of the display device can be reduced.

A touch sensor layer 187 may be disposed on the display area AA. The touch sensor layer 187 may include a first touch electrode 183, a first bridge electrode 184, a second touch electrode 185, and a second bridge electrode 186. The first touch electrode 183 and the second touch electrode 185 may have a mesh structure.

The first touch electrodes 183 adjacent to each other in the first direction DR1 may be connected by the first bridge electrode 184. The first bridge electrode 184 may be disposed on a different layer from the first touch electrodes 183. The second touch electrodes 185 adjacent to each other in the second direction DR2 may be connected by the second bridge electrode 186. The second bridge electrode 186 may be disposed on the same layer as the second touch electrodes 185 and formed integrally with the second touch electrodes 185.

The first touch electrode 183 and the second touch electrode 185 may be connected to the pads PD of the pad area PA through a touch routing line TRL and a connection line CNL. The touch routing line TRL may be connected to the connection line CNL through a contact hole in the link area LA. The touch routing line TRL may be formed by the same process as the first and second touch electrodes 183 and 185. The connection line CNL may cross the bending area BA and extend from the link area LA to the pad area PA.

The data lines DL may be connected to the data driver DIC through a connection line CNL′. The data line DL may be connected to the connection line CNL′ through a contact hole in the link area LA. The connection line CNL′ may cross the bending area BA and extend from the link area LA to the pad area PA.

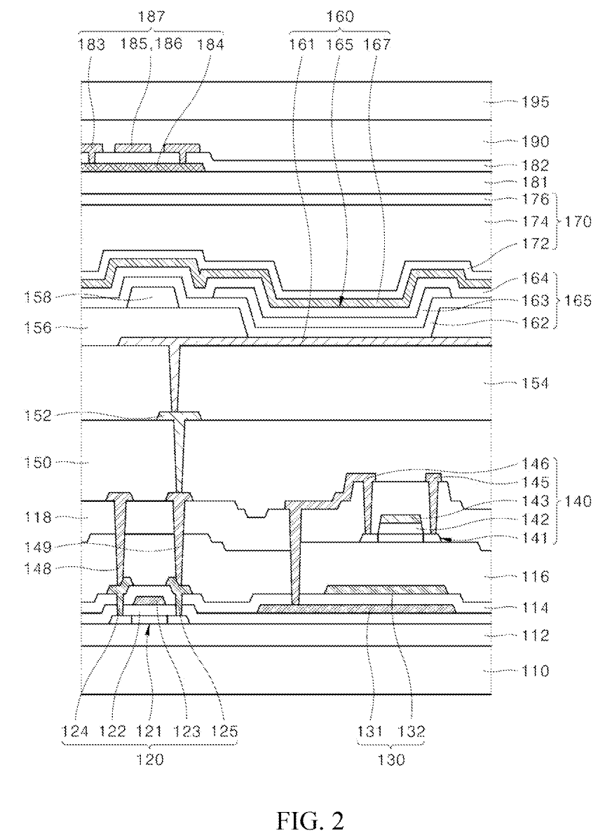

FIG. 2 is a cross-sectional view of the display device along line II-II in FIG. 1. FIG. 2 schematically shows a sub-pixel of the display device according to the embodiment of the present specification.

Referring to FIG. 2, the display device according to the embodiment of the present specification may include a substrate 110, a first thin film transistor 120, a storage capacitor 130, a second thin film transistor 140, a light-emitting element 160, and the touch sensor layer 187.

The substrate 110 may include an insulation material. The substrate 110 may include a flexible polymer material. The substrate 110 may have a multilayered structure. For example, the substrate 110 may include a lower substrate layer and an upper substrate layer that are formed of a polymer material such as polyimide (PI), and an intermediate layer disposed between the lower substrate layer and the upper substrate layer and formed of an inorganic insulation material.

A buffer layer 112 may be disposed on the substrate 110. The buffer layer 112 may completely cover the display area AA of the substrate 110. The buffer layer 112 may include an insulation material. For example, the buffer layer 112 may include an inorganic insulation material such as silicon oxide, silicon nitride, and silicon oxynitride. The buffer layer 112 may have a multilayered structure. For example, the buffer layer 112 may have a stacked structure of a first buffer layer and a second buffer layer including a different material from the first buffer layer.

A driving circuit may be positioned in each sub-pixel. The driving circuit may generate a driving current provided to the light-emitting element. The driving circuit may be electrically connected to signal lines. For example, the signal lines may include the gate line GL that applies gate signals, the data line DL that applies data signals, and power voltage supply lines that supply power voltages. For example, the driving circuit may include the first thin film transistor 120, the second thin film transistor 140, and the storage capacitor 130.

The first thin film transistor 120 may be electrically connected to the light-emitting element 160. The first thin film transistor 120 may include a first semiconductor pattern 121, a first gate insulating layer 122, a first gate electrode 123, a first source electrode 124, and a first drain electrode 125. The first semiconductor pattern 121 may be disposed on the buffer layer 112.

The first semiconductor pattern 121 may include a semiconductor material. For example, the first semiconductor pattern 121 may include a polycrystalline semiconductor material. For example, the first semiconductor pattern 121 may include low temperature poly-silicon (LTPS).

The first gate insulating layer 122 may be positioned on the first semiconductor pattern 121. The first gate insulating layer 122 may extend outward from the first semiconductor pattern 121. For example, side surfaces of the first semiconductor pattern 121 may be covered by the first gate insulating layer 122. For example, the first gate insulating layer 122 may extend along an upper surface of the buffer layer 112. The first gate insulating layer 122 may include an insulation material. For example, the first gate insulating layer 122 may include an inorganic insulation material such as silicon oxide, silicon nitride, and silicon oxynitride. The first gate insulating layer 122 may include a material having a high dielectric constant. For example, the first gate insulating layer 122 may include a high-K material such as hafnium oxide.

The first gate electrode 123 may be positioned on the first gate insulating layer 122. The first gate electrode 123 may include a conductive material. For example, the first gate electrode 123 may include a metal material such as aluminum (Al), chromium (Cr), copper (Cu), titanium (Ti), molybdenum (Mo), and tungsten (W). The first gate electrode 123 may be electrically insulated from the first semiconductor pattern 121 by the first gate insulating layer 122. The first gate electrode 123 may overlap a first channel area of the first semiconductor pattern 121.

A first interlayer insulating layer 114 may be positioned on the first gate electrode 123. The first interlayer insulating layer 114 may extend outward from the first gate electrode 123. For example, side surfaces of the first gate electrode 123 may be covered by the first interlayer insulating layer 114. The first interlayer insulating layer 114 may extend along an upper surface of the first gate insulating layer 122. The first interlayer insulating layer 114 may include an insulation material. For example, the first interlayer insulating layer 114 may include an inorganic insulation material such as silicon oxide, silicon nitride, and silicon oxynitride.

The first source electrode 124 and the first drain electrode 125 may be disposed on the first interlayer insulating layer 114. The first source electrode 124 and the first drain electrode 125 may include a conductive material. For example, the first source electrode 124 and the first drain electrode 125 may include a metal material such as aluminum (Al), chromium (Cr), copper (Cu), titanium (Ti), molybdenum (Mo), and tungsten (W). For example, the first source electrode 124 and the first drain electrode 125 may include a different material from the first gate electrode 123.

The first source electrode 124 and the first drain electrode 125 are electrically insulated to the first gate electrode 123 by the first interlayer insulating layer 114. The first source electrode 124 may be electrically connected to a first source area of the first semiconductor pattern 121. For example, the first source electrode 124 may come into direct contact with the first source area of the first semiconductor pattern 121 through a first source contact hole passing through the first gate insulating layer 122 and the first interlayer insulating layer 114. The first drain electrode 125 may be electrically connected to a first drain area of the first semiconductor pattern 121. For example, the first drain electrode 125 may come into direct contact with the first drain area of the first semiconductor pattern 121 through a first drain contact hole passing through the first gate insulating layer 122 and the first interlayer insulating layer 114.

The storage capacitor 130 may include a first storage electrode 131 and a second storage electrode 132 that are sequentially stacked. The first storage electrode 131 and the second storage electrode 132 may include a conductive material. For example, the first storage electrode 131 and the second storage electrode 132 may include a metal material such as aluminum (Al), chromium (Cr), copper (Cu), titanium (Ti), molybdenum (Mo), and tungsten (W).

The storage capacitor 130 may be formed, for example, using a process of forming the first thin film transistor 120. For example, the storage capacitor 130 may be positioned next to the first thin film transistor 120. For example, the first storage electrode 131 may include the same material as the first gate electrode 123. For example, the first storage electrode 131 may be positioned on the same layer as the first gate electrode 123. For example, the first storage electrode 131 may be formed by the same process as the first gate electrode 123. For example, the second storage electrode 132 may include the same material as the first source electrode 124 and the first drain electrode 125. For example, the second storage electrode 132 may be positioned on the same layer as the first source electrode 124 and the first drain electrode 125. For example, the second storage electrode 132 may be formed by the same process as the first source electrode 124 and the first drain electrode 125. For example, the first interlayer insulating layer 114 may extend between the first storage electrode 131 and the second storage electrode 132. The second storage electrode 132 may include a different material from the first storage electrode 131.

The second thin film transistor 140 may be electrically connected to the first thin film transistor 120. For example, the second thin film transistor 140 may include a second semiconductor pattern 141, a second gate insulating layer 142, a second gate electrode 143, a second source electrode 145, and a second drain electrode 146.

The second semiconductor pattern 141 may include a semiconductor material. The second semiconductor pattern 141 may include a different material from the first semiconductor pattern 121. For example, the second semiconductor pattern 141 may include an oxide semiconductor such as IGZO. The second semiconductor pattern 141 may be positioned on a different layer from the first semiconductor pattern 121. For example, a separation insulating layer 116 may be positioned on the first thin film transistor 120, and the second semiconductor pattern 141 may be positioned on the separation insulating layer 116. Accordingly, it is possible to prevent damage to the second semiconductor pattern 141 due to a process of forming the first semiconductor pattern 121. The separation insulating layer 116 may include an insulation material. For example, the separation insulating layer 116 may include an inorganic insulation material such as silicon oxide, silicon nitride, and silicon oxynitride. For example, the separation insulating layer 116 may have a multilayered structure including silicon oxide and silicon nitride.

The second gate insulating layer 142 may be disposed on the second semiconductor pattern 141. The second gate insulating layer 142 may overlap a second channel area of the second semiconductor pattern 141. The second gate insulating layer 142 may expose a second source area and a second drain area of the second semiconductor pattern 141. The second gate insulating layer 142 may include an insulation material. The second gate insulating layer 142 may include an inorganic insulation material such as silicon oxide, silicon nitride, and silicon oxynitride. The second gate insulating layer 142 may include the same material as the first gate insulating layer 122. For example, the second gate insulating layer 142 may have a multilayered structure.

The second gate electrode 143 may be disposed on the second gate insulating layer 142. For example, the second gate electrode 143 may overlap the second channel area of the second semiconductor pattern 141. The second gate electrode 143 may include a conductive material. For example, the second gate electrode 143 may include a metal material such as aluminum (Al), chromium (Cr), copper (Cu), titanium (Ti), molybdenum (Mo), and tungsten (W). For example, the second gate electrode 143 may include the same material as the first gate electrode 123. The second gate electrode 143 may be electrically insulated from the second semiconductor pattern 141 by the second gate insulating layer 142.

A second interlayer insulating layer 118 may be positioned on the second gate electrode 143. The second interlayer insulating layer 118 may extend outward from the second gate electrode 143. For example, side surfaces of the second gate electrode 143 and the second source area and the second drain area of the second semiconductor pattern 141 may be covered by the second interlayer insulating layer 118. The second interlayer insulating layer 118 may extend along an upper surface of the separation insulating layer 116. The second interlayer insulating layer 118 may include an insulation material. For example, the second interlayer insulating layer 118 may include the same material as the first interlayer insulating layer 114. For example, the second interlayer insulating layer 118 may include an inorganic insulation material such as silicon oxide, silicon nitride, and silicon oxynitride. For example, the second interlayer insulating layer 118 may have a multilayered structure including silicon oxide and silicon nitride.

The second source electrode 145 and the second drain electrode 146 may be disposed on the second interlayer insulating layer 118. The second source electrode 145 and the second drain electrode 146 may include a conductive material. For example, the second source electrode 145 and the second drain electrode 146 may include a metal material such as aluminum (Al), chromium (Cr), copper (Cu), titanium (Ti), molybdenum (Mo), and tungsten (W). For example, the second source electrode 145 and the second drain electrode 146 may include the same material as the first source electrode 124 and the first drain electrode 125. For example, the second source electrode 145 and the second drain electrode 146 may include a different material from the second gate electrode 143. For example, the second source electrode 145 and the second drain electrode 146 may have a multilayered structure of titanium (Ti)/aluminum (Al)/titanium (Ti).

The second source electrode 145 and the second drain electrode 146 may be electrically insulated from the second gate electrode 143 by the second interlayer insulating layer 118. The second source electrode 145 may be electrically connected to a second source area of the second semiconductor pattern 141. For example, the second source electrode 145 may come into direct contact with the second source area of the second semiconductor pattern 141 through a second source contact hole passing through the second interlayer insulating layer 118. The second drain electrode 146 may be electrically connected to the second drain area of the second semiconductor pattern 141. For example, the second drain electrode 146 may come into direct contact with the second drain area of the second semiconductor pattern 141 through a second drain contact hole passing through the second interlayer insulating layer 118.

The second thin film transistor 140 may be disposed on the storage capacitor 130. For example, the second semiconductor pattern 141 of the second thin film transistor 140 may overlap the storage capacitor 130. Light passing through the substrate 110 and traveling toward the second semiconductor pattern 141 may be blocked by the storage capacitor 130. Accordingly, a change in the characteristics of the second thin film transistor 140 due to external light can be prevented. The storage capacitor 130 may be electrically connected to the second drain electrode 146 of the second thin film transistor 140. For example, the second drain electrode 146 may come into direct contact with the first storage electrode 131 through a storage contact hole passing through the first interlayer insulating layer 114, the separation insulating layer 116, and the second interlayer insulating layer 118.

An intermediate source electrode 148 and an intermediate drain electrode 149 may be positioned on the second interlayer insulating layer 118. The intermediate source electrode 148 and the intermediate drain electrode 149 may include a conductive material. For example, the intermediate source electrode 148 and the intermediate drain electrode 149 may include a metal material such as aluminum (Al), chromium (Cr), copper (Cu), titanium (Ti), molybdenum (Mo), and tungsten (W). The intermediate source electrode 148 and the intermediate drain electrode 149 may include the same material as the second source electrode 145 and the second drain electrode 146. For example, the second source electrode 145, the second drain electrode 146, the intermediate source electrode 148, and the intermediate drain electrode 149 may be formed simultaneously. For example, the second source electrode 145, the second drain electrode 146, the intermediate source electrode 148, and the intermediate drain electrode 149 may have a multilayered structure of titanium (Ti)/aluminum (Al)/titanium (Ti).

The intermediate source electrode 148 may be electrically connected to the first source electrode 124 of the first thin film transistor 120. For example, the intermediate source electrode 148 may come into direct contact with the first source electrode 124 of the first thin film transistor 120 through a first intermediate contact hole passing through the separation insulating layer 116 and the second interlayer insulating layer 118. The intermediate drain electrode 149 may be electrically connected to the first drain electrode 125 of the first thin film transistor 120. For example, the intermediate drain electrode 149 may come into direct contact with the first drain electrode 125 of the first thin film transistor 120 through a second intermediate contact hole passing through the separation insulating layer 116 and the second interlayer insulating layer 118.

The light-emitting element 160 may be disposed on the driving circuit. For example, the first thin film transistor 120, the second thin film transistor 140, and the storage capacitor 130 of each sub-pixel may be positioned between the substrate 110 and the light-emitting element 160.

A first planarization layer 150 and a second planarization layer 154 may be sequentially stacked between the driving circuit and the light-emitting element 160. The first planarization layer 150 and the second planarization layer 154 may cover a step caused by the driving circuit to provide a flat surface. For example, the first planarization layer 150 and the second planarization layer 154 may include an organic insulation material.

An intermediate contact electrode 152 may be disposed on the first planarization layer 150. The light-emitting element 160 may be disposed on the second planarization layer 154. The light-emitting element 160 may include a first electrode 161, a light-emitting layer 165, and a second electrode 167. The light-emitting element 160 may be electrically connected to the intermediate drain electrode 149 through the intermediate contact electrode 152, and is thus electrically connected to the first drain electrode 125 of the first thin film transistor 120. For example, the intermediate contact electrode 152 may be connected to the intermediate drain electrode 149 by passing through the first planarization layer 150, and the first electrode 161 of the light-emitting element 160 may be connected to the intermediate contact electrode 152 by passing through the second planarization layer 154. The intermediate contact electrode 152 may include a conductive material. For example, the intermediate contact electrode 152 may include a metal material such as aluminum (Al), chromium (Cr), copper (Cu), titanium (Ti), molybdenum (Mo), and tungsten (W). For example, the intermediate contact electrode 152 may have a multilayered structure of titanium (Ti)/aluminum (Al)/titanium (Ti).

A bank layer 156 may be disposed on the second planarization layer 154. The bank layer 156 may include an organic insulation material. For example, the bank layer 156 may be formed of a photosensitive acryl-based or polyimide-based organic material. The bank layer 156 may cover an edge of the first electrode 161. The bank layer 156 may have an opening that exposes a part of the first electrode 161. The light-emitting layer 165 and the second electrode 167 of the light-emitting element 160 may be stacked on a part of the first electrode 161 exposed by the bank layer 156. A light-emitting area may be defined by the part of the first electrode 161 exposed by the opening of the bank layer 156. The first electrode 161 may include a conductive material. The first electrode 161 may have high reflectivity. For example, the first electrode 161 may include a metal material such as aluminum (Al) or silver (Ag). The first electrode 161 may have a multilayered structure. For example, the first electrode 161 may have a structure in which a metal such as aluminum (Al) or silver (Ag) is disposed between transparent conductive materials such as ITO and IZO.

The light-emitting layer 165 may extend onto the bank layer 156. The light-emitting layer 165 may include a light-emitting material layer 163. For example, the light-emitting material layer 163 may include a light-emitting material formed of an organic material. The light-emitting layer 165 may have a multilayered structure. For example, the light-emitting layer 165 may include at least one of a first light-emitting common layer 162 positioned between the first electrode 161 and the light-emitting material layer 163 and a second light-emitting common layer 164 positioned between the light-emitting material layer 163 and the second electrode 167. For example, the first light-emitting common layer 162 may include at least one of a hole injection layer (HIL) and a hole transport layer (HTL). The second light-emitting common layer 164 may include at least one of an electron transport layer (ETL) and an electron injection layer (EIL).

For example, when the sub-pixels of each pixel emit light of different colors, the light-emitting material layer 163 of each sub-pixel may be separated from the light-emitting material layer 163 of an adjacent sub-pixel. The light-emitting material layer 163 of each sub-pixel may be formed separately using a fine metal mask (FMM). An end portion of the light-emitting material layer 163 may be positioned on the bank layer 156.

For example, a spacer 158 may be disposed on the bank layer 156. The spacer 158 can prevent damage to the bank layer 156 and the light-emitting material layer 163 formed first on the adjacent sub-pixel by the fine metal mask. For example, the spacer 158 may be formed of a photosensitive acryl-based or polyimide-based organic material. The bank layer 156 and the spacer 158 may be formed simultaneously by a single photolithography process, but are not limited thereto. The bank layer 156 and the spacer 158 may be formed by separate processes, respectively.

The first light-emitting common layer 162 and the second light-emitting common layer 164 of the light-emitting layer 165 may extend along a surface of the bank layer 156. The first light-emitting common layer 162 and the second light-emitting common layer 164 of the light-emitting layer 165 may cover an upper surface and side surfaces of the spacer 158. For example, the first light-emitting common layer 162 and the second light-emitting common layer 164 may be disposed in common in adjacent sub-pixels. For example, each of the first light-emitting common layer 162 and the second light-emitting common layer 164 may be disposed in common in all pixels in the display area AA.

The second electrode 167 may be disposed in common in adjacent sub-pixels. For example, the second electrode 167 may be disposed in common in all pixels in the display area AA. The second electrode 167 may include a conductive material. For example, the second electrode 167 may be a transparent electrode formed of a transparent conductive material such as ITO and IZO.

An encapsulation part 170 may be positioned on the light-emitting element 160. The encapsulation part 170 can prevent damage to the light-emitting elements 160 due to an external impact and moisture. The encapsulation part 170 may have a multilayered structure. For example, the encapsulation part 170 may include a first encapsulation layer 172, a second encapsulation layer 174, and a third encapsulation layer 176 that are sequentially stacked. For example, the first encapsulation layer 172 and the third encapsulation layer 176 may include an inorganic insulation material, and the second encapsulation layer 174 may include an organic insulation material.

The encapsulation part 170 may extend outward from the display area AA. At least one encapsulation dam may be disposed in the non-display area NAA. For example, the encapsulation dam may include at least one organic insulation material. For example, the encapsulation dam may be positioned on the first planarization layer 150. For example, the encapsulation dam may include the same material as the second planarization layer 154. The sealing dam may have a closed loop shape surrounding the display area AA of the substrate 110. Since movement of the second encapsulation layer 174 having mobility may be blocked by the encapsulation dam, the second encapsulation layer 174 may be positioned only on a part of the substrate 110 defined by the encapsulation dam. The third encapsulation layer 176 may come into direct contact with the first encapsulation layer 172 outside the second encapsulation layer 174.

The touch sensor layer 187 may be disposed on the encapsulation part 170. The touch sensor layer 187 may include the first touch electrode 183, the first bridge electrode 184, the second touch electrode 185, and the second bridge electrode 186.

A touch buffer layer 181 may be disposed between the encapsulation part 170 and the touch sensor layer 187. The touch buffer layer 181 can prevent the encapsulation part 170 and the light-emitting element 160 from being damaged by the process of forming the first bridge electrode 184, the first and second touch electrodes 183 and 185, and the second bridge electrode 186. For example, an upper surface of the encapsulation part 170 may be covered by the touch buffer layer 181. For example, the touch buffer layer 181 may extend to the non-display area NAA. The touch buffer layer 181 may include an insulation material. For example, the touch buffer layer 181 may include an inorganic insulation material such as silicon oxide, silicon nitride, and silicon oxynitride.

The first bridge electrode 184 may be disposed on the touch buffer layer 181. The touch insulating layer 182 may be disposed on the first bridge electrode 184. The touch insulating layer 182 may extend along an upper surface of the touch buffer layer 181. For example, the touch insulating layer 182 may extend to the non-display area NAA. For example, the touch insulating layer 182 may include an inorganic insulation material such as silicon oxide, silicon nitride, and silicon oxynitride.

The first touch electrodes 183 and the second touch electrodes 185 may be disposed on the touch insulating layer 182. The first bridge electrode 184 may electrically connect adjacent first touch electrodes 183. The first touch electrodes 183 may be connected to the first bridge electrode 184 through touch contact holes passing through the touch insulating layer 182. The second bridge electrode 186 may be disposed on the touch insulating layer 182 and formed integrally with the second touch electrodes 185.

The first and second touch electrodes 183 and 185 and the first and second bridge electrodes 184 and 186 may include a conductive material. For example, the first and second touch electrodes 183 and 185 and the first and second bridge electrodes 184 and 186 may include a metal material such as aluminum (Al), chromium (Cr), copper (Cu), titanium (Ti), molybdenum (Mo), and tungsten (W). For example, the first and second touch electrodes 183 and 185 and the first and second bridge electrodes 184 and 186 may have a multilayered structure of titanium (Ti)/aluminum (Al)/titanium (Ti). For example, the first and second touch electrodes 183 and 185 and the first and second bridge electrodes 184 and 186 may overlap the bank layer 156. Light emitted from each light-emitting element 160 may not be blocked by the first and second touch electrodes 183 and 185 and the first and second bridge electrodes 184 and 186.

A touch protective layer 190 may be disposed on the touch sensor layer 187. The touch protective layer 190 can prevent damage to the touch sensor layer 187 due to an external impact and moisture. The touch protective layer 190 may include an insulation material. For example, the touch protective layer 190 may include an organic insulation material. For example, the touch protective layer 190 may be formed of a photosensitive acryl-based or polyimide-based organic material. The touch protective layer 190 may extend to the non-display area NAA.

A cover layer 195 may be disposed on the touch protective layer 190. For example, the cover layer 195 may include an organic insulation material. For example, the cover layer 195 may be formed of an acryl-based, polyimide-based, epoxy-based, or silane-based resin. The touch protective layer 190 may extend to the non-display area NAA. The cover layer 195 may extend to the non-display area NAA.

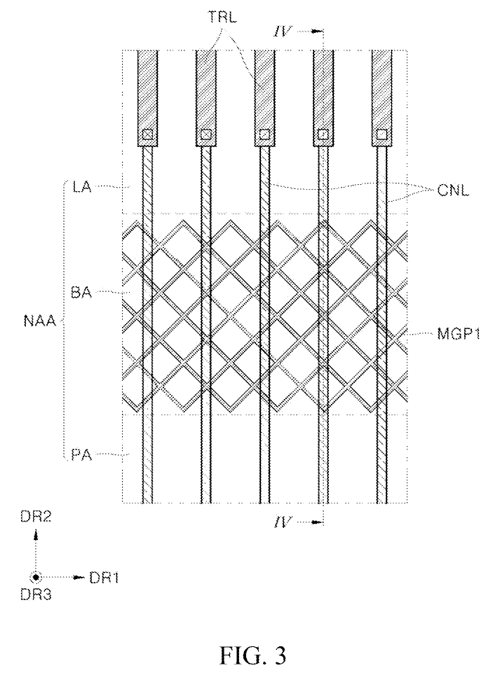

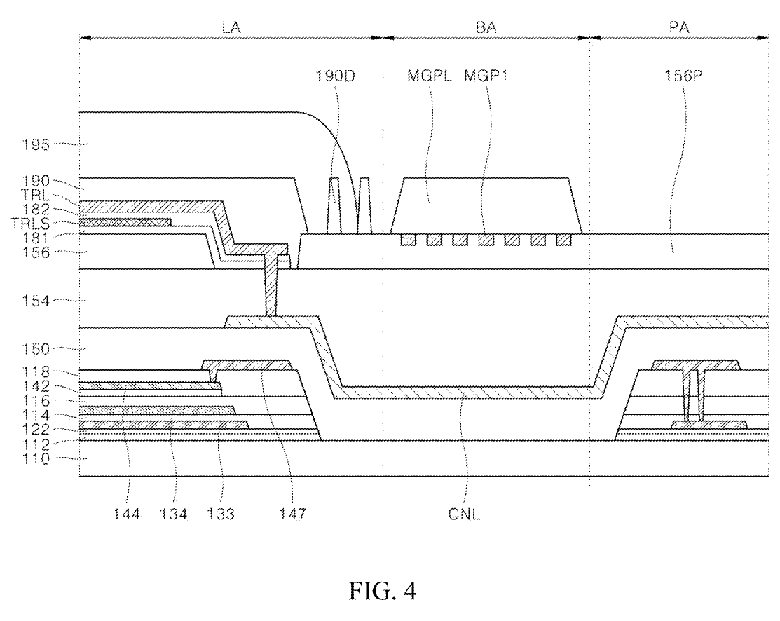

FIG. 3 is an enlarged view of area III in FIG. 1. FIG. 4 is a cross-sectional view of the display device along line IV-IV in FIG. 3. FIG. 3 is a plan view showing a part of the non-display area NAA of the display panel 100. FIG. 3 shows a structure in which the touch routing line TRL of the link area LA is connected to the pad area PA by the connection line CNL.

Referring to FIG. 3, a plurality of connection lines CNL connected one-to-one to a plurality of touch routing lines TRL may cross the bending area BA and extend from the link area LA to the pad area PA. A metal grid pattern MGP1 overlapping the plurality of connection lines CNL may be disposed in the bending area BA. The metal grid pattern MGP1 may be disposed on a different layer from the plurality of connection lines CNL. The metal grid pattern MGP1 may be disposed on the plurality of connection lines CNL. As shown in FIG. 3, the metal grid pattern MGP1 according to the present embodiment may be a metal grid pattern having rhombus-shaped openings in a plan view. Vertices of each rhombus shape may be disposed adjacent to each other in the first direction DR1 and the second direction DR2. Grid lines of the metal grid pattern MGP1 may extend in an inclined direction with respect to the first direction DR1 or the second direction DR2.

The metal grid pattern MGP1 may not be locally disposed to overlap the connection lines CNL connected to the touch routing lines TRL, but disposed to overlap the plurality of connection lines CNL, CNL′ across the entirety of the bending area BA extending in the first direction DR1 in FIG. 1. Thus, the metal grid pattern MGP1 may also be disposed to overlap connection lines CNL′ connected to the data lines DL (see FIG. 1).

Referring to FIG. 4, the buffer layer 112, the first gate insulating layer 122, the first interlayer insulating layer 114, the separation insulating layer 116, and the second interlayer insulating layer 118 may be disposed in the link area LA and the pad area PA of the substrate 110. The second gate insulating layer 142 may be further disposed between the separation insulating layer 116 and the second interlayer insulating layer 118 in the link area LA of the substrate 110.

However, the buffer layer 112, the first gate insulating layer 122, the first interlayer insulating layer 114, the separation insulating layer 116, and the second interlayer insulating layer 118 that are formed of an inorganic insulation material that is vulnerable to cracks may not be disposed in the bending area BA of the substrate 110. The buffer layer 112, the first gate insulating layer 122, the first interlayer insulating layer 114, the separation insulating layer 116, and the second interlayer insulating layer 118 may expose the bending area BA of the substrate 110. End portions of the buffer layer 112, the first gate insulating layer 122, the first interlayer insulating layer 114, the separation insulating layer 116, and the second interlayer insulating layer 118 that extend from the display area AA may be disposed within the link area LA.

A first signal line 133, a second signal line 134, and a third signal line 144 may be disposed in the link area LA of the substrate 110. The first signal line 133 may be disposed between the first gate insulating layer 122 and the first interlayer insulating layer 114. The first signal line 133 may be formed of the same material as the first gate electrode 123 and formed by the same process as the first gate electrode 123. The second signal line 134 may be disposed between the first interlayer insulating layer 114 and the separation insulating layer 116. The second signal line 134 may be formed of the same material as the first source electrode 124 and the first drain electrode 125 and formed by the same process as the first source electrode 124 and the first drain electrode 125. The third signal line 144 may be disposed between the separation insulating layer 116 and the second interlayer insulating layer 118. The third signal line 144 may be formed of the same material as the second gate electrode 143 and formed by the same process as the second gate electrode 143. The second gate insulating layer 142 may be further disposed between the third signal line 144 and the separation insulating layer 116.

In addition, an intermediate line 147 may be disposed on the second interlayer insulating layer 118 in the link area LA of the substrate 110. The intermediate line 147 may be formed of the same material as the second source electrode 145 and the second drain electrode 146 and formed by the same process as the second source electrode 145 and the second drain electrode 146.

The first planarization layer 150 covering the intermediate line 147 may be disposed on the second interlayer insulating layer 118. The first planarization layer 150 extending from the display area AA may be disposed continuously in the link area LA, the bending area BA, and the pad area PA of the substrate 110. The first planarization layer 150 may be directly disposed in the bending area BA of the substrate 110.

The connection line CNL may be disposed on the first planarization layer 150 and disposed in the link area LA, the bending area BA, and the pad area PA of the substrate 110. The connection line CNL may be formed of the same material as the intermediate contact electrode 152 and formed by the same process as the intermediate contact electrode 152.

The second planarization layer 154 covering the connection line CNL may be disposed on the first planarization layer 150. The second planarization layer 154 extending from the display area AA may be disposed continuously in the link area LA, the bending area BA, and the pad area PA of the substrate 110. The second planarization layer 154 can prevent damage to the connection line CNL due to an external impact and moisture.

The bank layer 156, the touch buffer layer 181, and the touch insulating layer 182 may be disposed on the second planarization layer 154 in the link area LA of the non-display area NAA. The touch buffer layer 181 and the touch insulating layer 182 may extend outward from the bank layer 156. The touch buffer layer 181 and the touch insulating layer 182 may cover side surfaces of the bank layer 156. A stress relief layer 156P may be disposed in the link area LA, the bending area BA, and the pad area PA of the non-display area NAA. The stress relief layer 156P may be formed of the same material as the bank layer 156 and formed by the same process as the bank layer 156. The stress relief layer 156P may be disposed to be spaced apart from the bank layer 156.

The touch routing line TRL may be disposed in the link area LA of the non-display area NAA. The touch routing line TRL may be disposed on the touch insulating layer 182. The touch routing line TRL may be connected to the connection line CNL through a contact hole passing through the second planarization layer 154, the touch buffer layer 181, and the touch insulating layer 182. The touch routing line TRL may be formed of the same material as the first and second touch electrodes 183 and 185 and formed by the same process as the first and second touch electrodes 183 and 185. An auxiliary touch routing line TRLS may be disposed in the link area LA of the non-display area NAA. The auxiliary touch routing line TRLS may be disposed on the touch buffer layer 181. The auxiliary touch routing line TRLS may be disposed between the touch buffer layer 181 and the touch insulating layer 182. The auxiliary touch routing line TRLS may be formed of the same material as the first bridge electrode 184 and formed by the same process as the first bridge electrode 184. The auxiliary touch routing line TRLS may be electrically connected to the touch routing line TRL.

The touch protective layer 190 may cover the touch routing line TRL. An end portion of the touch protective layer 190 may come into contact with an end portion of the stress relief layer 156P. A plurality of partitions 190D may be disposed on a part of the stress relief layer 156P. The plurality of partitions 190D may be disposed in the link area LA, but are not limited thereto. Some of the plurality of partitions 190D may be disposed in the bending area BA. The plurality of partitions 190D may serve as a dam to prevent the organic material forming the cover layer 195 from flowing to the outside of the display panel 100 during the process of forming the cover layer 195 disposed on the touch protective layer 190. The partition 190D may have a closed loop shape surrounding the display area AA of the substrate 110. The plurality of partitions 190D may be formed of the same material as the touch protective layer 190 and formed by the same process as the touch protective layer 190.

The cover layer 195 may be disposed in the link area LA of the non-display area NAA. The cover layer 195 may come into direct contact with an upper surface and side surfaces of the touch protective layer 190. The cover layer 195 may cover one of the plurality of partitions 190D.

The metal grid pattern MGP1 and a grid protective layer MGPL may be disposed in the bending area BA of the non-display area NAA. The metal grid pattern MGP1 may be disposed on the connection line CNL. The metal grid pattern MGP1 may be embedded in an engraved shape in an upper portion of the stress relief layer 156P. The metal grid pattern MGP1 may be disposed in a groove provided in an upper surface of the stress relief layer 156P. The metal grid pattern MGP1 may be formed of the same material as the first and second touch electrodes 183 and 185 and formed by the same process as the first and second touch electrodes 183 and 185. The metal grid pattern MGP1 may be formed of the same material as the touch routing line TRL and formed by the same process as the touch routing line TRL. The grid protective layer MGPL may cover the metal grid pattern MGP1 and be disposed on the upper surface of the stress relief layer 156P. The grid protective layer MGPL can protect the metal grid pattern MGP1 from an external impact or moisture. The grid protective layer MGPL may be formed of the same material as the touch protective layer 190 and formed by the same process as the touch protective layer 190.

The display device according to one embodiment of the present specification may include the metal grid pattern MGP1 embedded in the stress relief layer 156P disposed on the connection line CNL in the bending area BA, thereby efficiently distributing the tensile stress applied to the stress relief layer 156P when the bending area of the display device is bent. Accordingly, cracks can be prevented from occurring in the stress relief layer 156P when the bending area of the display device is bent, and cracks in the stress relief layer 156P can be prevented from propagating and causing cracks in the connection line CNL.

In addition, in the display device according to one embodiment of the present specification, the tensile stress applied to the stress relief layer 156P when the bending area of the display device is bent can be distributed, thereby further reducing the curvature of the bending area BA. Accordingly, the lower bezel area of the display device according to the embodiments of the present specification can be further reduced.

In addition, in the display device according to one embodiment of the present specification, since the tensile stress applied to the organic material layer when the bending area of the display device is bent can be distributed, the resin layer previously additionally coated on the bending area in order to reduce the tensile stress by adjusting a position of a neural surface of the bending area can be omitted.

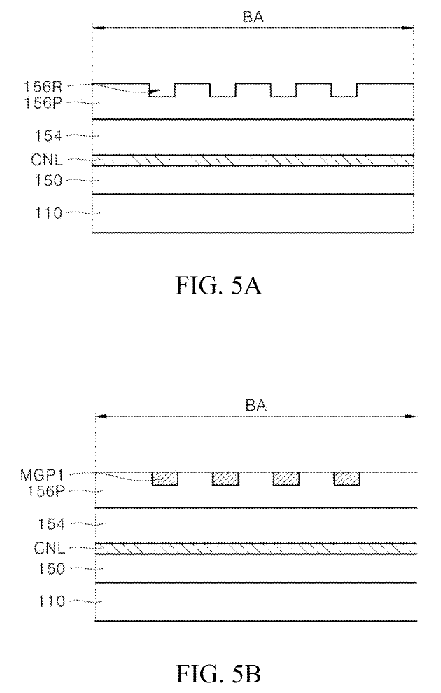

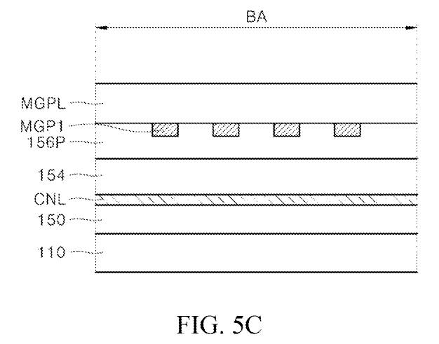

FIGS. 5A to 5C are cross-sectional views showing a method of manufacturing a metal grid pattern according to one embodiment of the present specification. For convenience of description, FIGS. 5A to 5C show only the bending area BA of the non-display area NAA.

Referring to FIG. 5A, the first planarization layer 150, the connection line CNL, the second planarization layer 154, and the stress relief layer 156P may be stacked in the bending area BA of the substrate 110. A groove 156R in which a metal grid pattern is disposed may be formed in the stress relief layer 156P. For example, the stress relief layer 156P may be formed by the same process as the bank layer 156. For example, when the opening of the bank layer 156 is formed, the groove 156R of the stress relief layer 156P may be formed together. Since the bank layer 156 and the stress relief layer 156P are formed of a photosensitive acryl-based or polyimide-based organic material, the opening of the bank layer 156 and the groove 156R of the stress relief layer 156P may be simultaneously formed by a single photolithography process using a halftone mask.

Referring to FIG. 5B, the metal grid pattern MGP1 may be formed in the groove 156R of the stress relief layer 156P. The metal grid pattern MGP1 may be formed by the same process as the first and second touch electrodes 183 and 185 or the touch routing line TRL. During an etching process for patterning the first and second touch electrodes 183 and 185 or the touch routing line TRL, a metal material formed in an area other than the groove 156R of the stress relief layer 156P may be removed so that the metal grid pattern MGP1 may be embedded in the groove 156R of the stress relief layer 156P.

Referring to FIG. 5C, the grid protective layer MGPL covering the metal grid pattern MGP1 may be formed on the stress relief layer 156P. The grid protective layer MGPL may be formed by the same process as the touch protective layer 190. Since the touch protective layer 190 and the grid protective layer MGPL are formed of a photosensitive acryl-based or polyimide-based organic material, the touch protective layer 190 and the grid protective layer MGPL may be simultaneously formed by a single photolithography process.

According to the manufacturing method of one embodiment of the present specification, since a metal grid pattern and a grid protective layer may be formed through some modifications of conventional processes, the metal grid pattern and the grid protective layer can be easily formed in the bending area without adding a manufacturing process and a mask.

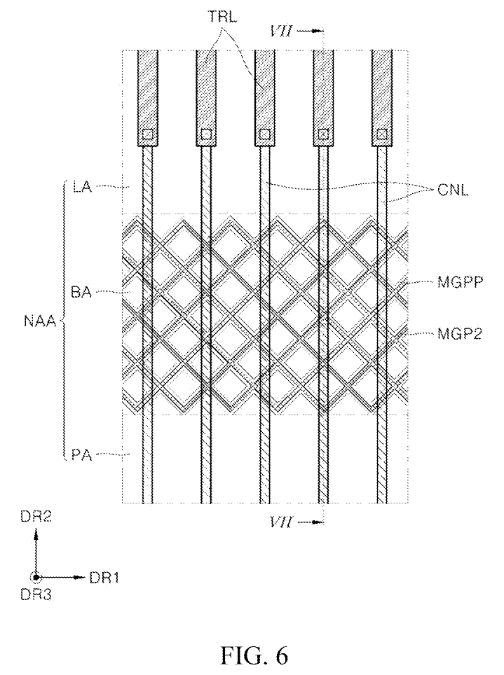

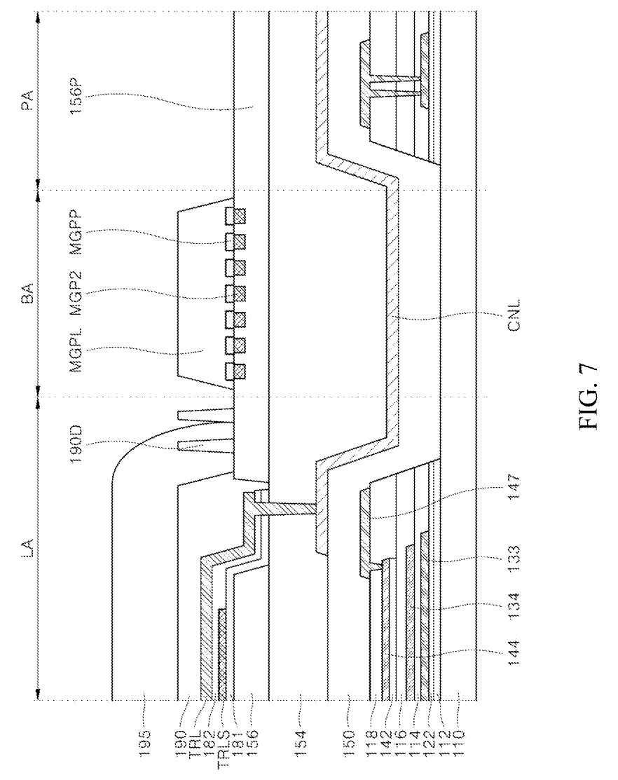

FIG. 6 is a plan view showing a bending area of the display device according to one embodiment of the present specification. FIG. 7 is a cross-sectional view of the display device along line VII-VII in FIG. 6.

Referring to FIG. 6, a metal grid pattern MGP2 and a grid protective pattern MGPP that overlap the plurality of connection lines CNL may be disposed in the bending area BA. The metal grid pattern MGP2 may be disposed on a different layer from the plurality of connection lines CNL. The metal grid pattern MGP2 may be disposed on the plurality of connection lines CNL. The grid protective pattern MGPP may be disposed on the metal grid pattern MGP2.

As shown in FIG. 6, the metal grid pattern MGP2 according to the present embodiment may be a metal grid pattern having rhombus-shaped openings in a plan view. Vertices of each rhombus shape may be disposed adjacent to each other in the first direction DR1 and the second direction DR2. Grid lines of the metal grid pattern MGP2 may extend in an inclined direction with respect to the first direction DR1 or the second direction DR2. Similar to the metal grid pattern MGP2, the grid protective pattern MGPP may be a grid pattern having rhombus-shaped openings. Widths of grid lines of the grid protective patterns MGPP may be greater than widths of grid lines of the metal grid patterns MGP2.

The metal grid pattern MGP2 may not be locally disposed to overlap the connection lines CNL connected to the touch routing lines TRL, but disposed to overlap the plurality of connection lines CNL, CNL′ across the entirety of the bending area BA extending in the first direction DR1 in FIG. 1. Thus, the metal grid pattern MGP2 may also be disposed to overlap the connection lines CNL′ connected to the data lines DL.

Referring to FIG. 7, the metal grid pattern MGP2, the grid protective pattern MGPP, and the grid protective layer MGPL may be disposed in the bending area BA of the non-display area NAA. The metal grid pattern MGP2 may be disposed on the connection line CNL. The metal grid pattern MGP2 may be embedded in an engraved shape in an upper portion of the stress relief layer 156P. The metal grid pattern MGP2 may be disposed in a groove provided in an upper surface of the stress relief layer 156P. The metal grid pattern MGP2 may be formed of the same material as the first bridge electrode 184 and formed by the same process as the first bridge electrode 184. The metal grid pattern MGP2 may be formed of the same material as the auxiliary touch routing line TRLS and formed by the same process as the auxiliary touch routing line TRLS. The grid protective pattern MGPP may completely cover the metal grid pattern MGP2. The grid line of the grid protective pattern MGPP may completely cover an upper surface of the grid line of the metal grid pattern MGP2. The grid protective pattern MGPP can protect the metal grid pattern MGP2 from external moisture. The grid protective pattern MGPP may be formed of the same material as the touch insulating layer 182 and formed by the same process as the touch insulating layer 182. The grid protective layer MGPL may cover the grid protective pattern MGPP and may be disposed on the upper surface of the stress relief layer 156P. The grid protective layer MGPL can protect the metal grid pattern MGP2 from an external impact or moisture. The grid protective layer MGPL may be formed of the same material as the touch protective layer 190 and formed by the same process as the touch protective layer 190. The embodiment of FIG. 7 differs from the embodiment of FIG. 4 in that some configurations disposed in the bending area BA of the non-display area NAA are different, and other configurations are the same.

The display device according to one embodiment of the present specification may include the metal grid pattern MGP2 embedded in the stress relief layer 156P disposed on the connection line CNL in the bending area BA, thereby efficiently distributing the tensile stress applied to the stress relief layer 156P when the bending area of the display device is bent. Accordingly, cracks can be prevented from occurring in the stress relief layer 156P when the bending area of the display device is bent, and cracks in the stress relief layer 156P can be prevented from propagating and causing cracks in the connection line CNL.

In addition, in the display device according to one embodiment of the present specification, the tensile stress applied to the stress relief layer 156P when the bending area of the display device is bent can be distributed, thereby further reducing the curvature of the bending area BA. Accordingly, the lower bezel area of the display device according to the embodiments of the present specification can be further reduced.

In addition, in the display device according to one embodiment of the present specification, since the tensile stress applied to the organic material layer when the bending area of the display device is bent can be distributed, the resin layer previously additionally coated on the bending area in order to reduce the tensile stress by adjusting a position of a neutral surface of the bending area can be omitted.

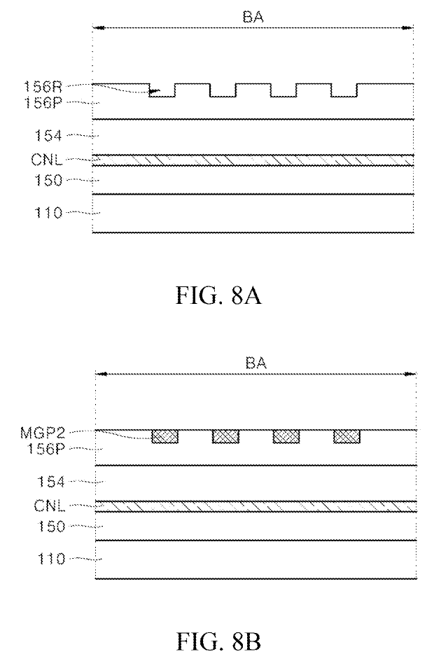

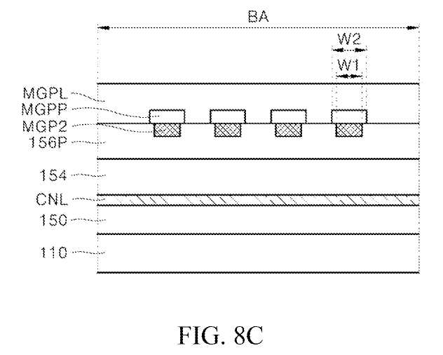

FIGS. 8A to 8C are cross-sectional views showing a method of manufacturing a metal grid pattern according to one embodiment of the present specification. For convenience of description, FIGS. 8A to 8C show only the bending area BA of the non-display area NAA.

Referring to FIG. 8A, the first planarization layer 150, the connection line CNL, the second planarization layer 154, and the stress relief layer 156P may be stacked in the bending area BA of the substrate 110. The groove 156R in which a metal grid pattern is disposed may be formed in the stress relief layer 156P. For example, the stress relief layer 156P may be formed by the same process as the bank layer 156. For example, when the opening of the bank layer 156 is formed, the groove 156R of the stress relief layer 156P may be formed together. Since the bank layer 156 and the stress relief layer 156P are formed of a photosensitive acryl-based or polyimide-based organic material, the opening of the bank layer 156 and the groove 156R of the stress relief layer 156P may be simultaneously formed by a single photolithography process using a halftone mask.

Referring to FIG. 8B, the metal grid pattern MGP2 may be formed in the groove 156R of the stress relief layer 156P. The metal grid pattern MGP2 may be formed by the same process as the first bridge electrode 184 or the auxiliary touch routing line TRLS. During an etching process for patterning the first bridge electrode 184 or the auxiliary touch routing line TRLS, the metal material formed in the area other than the groove 156R of the stress relief layer 156P may be removed so that the metal grid pattern MGP2 may be embedded in the groove 156R of the stress relief layer 156P.

Referring to FIG. 8C, the grid protective pattern MGPP covering the metal grid pattern MGP2 and the grid protective layer MGPL may be formed on the stress relief layer 156P. The grid protective pattern MGPP may be formed by the same process as the touch insulating layer 182. The grid protective pattern MGPP may have the shape similar to that of the metal grid pattern MGP2 and completely cover the metal grid pattern MGP2. The grid line of the grid protective pattern MGPP may completely cover an upper surface of the grid line of the metal grid pattern MGP2. A width W2 of the grid line of the grid protective pattern MGPP may be greater than a width W1 of the grid lines of the metal grid pattern MGP2. The grid protective layer MGPL may be formed by the same process as the touch protective layer 190. Since the touch protective layer 190 and the grid protective layer MGPL are formed of a photosensitive acryl-based or polyimide-based organic material, the touch protective layer 190 and the grid protective layer MGPL may be simultaneously formed by a single photolithography process.

According to the manufacturing method of one embodiment of the present specification, since the metal grid pattern, the grid protective pattern, and the grid protective layer may be formed through some modifications of conventional processes, the metal grid pattern, the grid protective pattern, and the grid protective layer can be easily formed in the bending area without adding a manufacturing process and a mask.

The display device including the metal grid patterns MGP1 and MGP2 having the rhombus-shaped openings has been described so far. However, the embodiments of the present specification are not limited thereto.

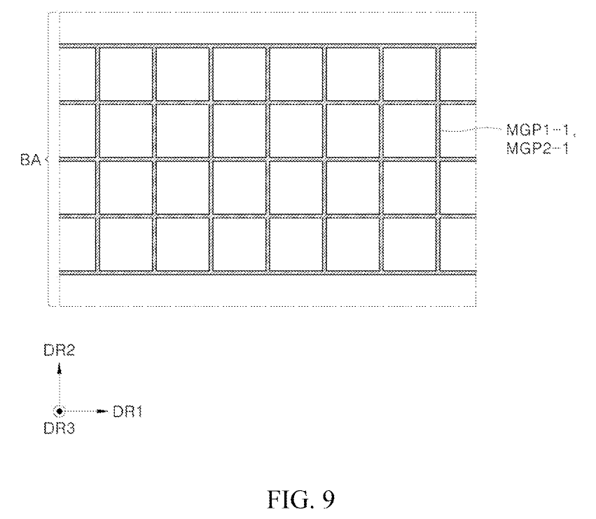

FIG. 9 is a plan view showing a metal grid pattern of the display device according to one embodiment of the present specification.

Referring to FIG. 9, metal grid patterns MGP1-1 and MGP2-1 disposed in the bending area BA of the substrate 110 may be metal grid patterns having quadrangular openings. The quadrangular openings may form rows and columns in the first direction DR1 and the second direction DR2. Grid lines of the metal grid patterns MGP1-1 and MGP2-1 may extend in the first direction DR1 and the second direction DR2. The metal grid pattern MGP1-1 corresponds to a modified example of the metal grid pattern MGP1, and the metal grid pattern MGP2-1 corresponds to a modified example of the metal grid pattern MGP2. As another modified example, metal grid patterns in which quadrangular openings are disposed in a zigzag manner in the first direction DR1 or the second direction DR2 may also be applied to the bending area BA of the display panel 100.

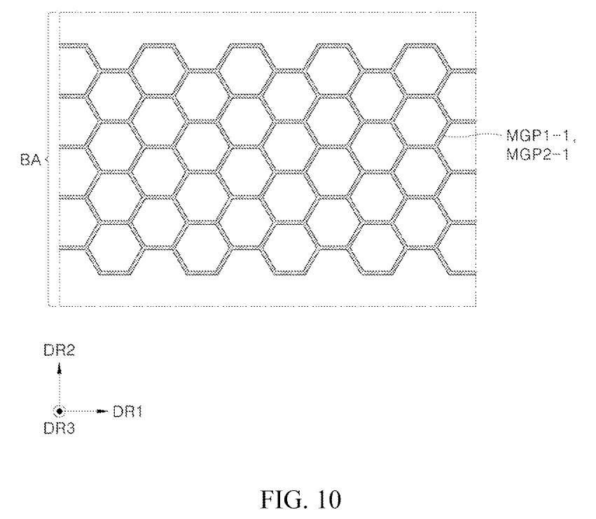

FIG. 10 is a plan view showing a metal grid pattern of the display device according to one embodiment of the present specification.

Referring to FIG. 10, the metal grid patterns MGP1-2 and MGP2-2 disposed in the bending area BA of the substrate 110 may be metal grid patterns in which hexagonal openings are disposed in a honeycomb shape. The metal grid pattern MGP1-2 corresponds to a modified example of the metal grid pattern MGP1, and the metal grid pattern MGP2-2 corresponds to a modified example of the metal grid pattern MGP2.

A display device according to various embodiments of the present specification may be described as follows.

According to embodiments of the present specification, there is provided a display device including a substrate including a display area and a bending area, a connection line crossing the bending area of the substrate, a planarization layer covering the connection line in the bending area, a stress relief layer disposed on the planarization layer in the bending area, and a metal grid pattern disposed on the connection line in the bending area, in which a groove is disposed in an upper surface of the stress relief layer, and the metal grid pattern is disposed to correspond to the groove.

According to some embodiments of the present specification, the metal grid pattern may be integrally disposed on the entirety of the bending area.

According to some embodiments of the present specification, the metal grid pattern may have rhombus-shaped openings.

According to some embodiments of the present specification, the metal grid pattern may have quadrangular openings.

According to some embodiments of the present specification, the metal grid pattern may have hexagonal openings disposed in a honeycomb shape.

According to some embodiments of the present specification, the stress relief layer may include the same material as a bank layer disposed in the display area.

According to some embodiments of the present specification, the metal grid pattern may include the same material as a touch electrode disposed in the display area.

According to some embodiments of the present specification, the display device may further include a grid protective layer covering the metal grid pattern and disposed on the stress relief layer in the bending area.

According to some embodiments of the present specification, the grid protective layer may include the same material as a touch protective layer disposed in the display area.

According to some embodiments of the present specification, the metal grid pattern may include the same material as a first bridge electrode disposed in the display area.

According to some embodiments of the present specification, the display device may further include a grid protective pattern overlapping the metal grid pattern in the bending area.

According to some embodiments of the present specification, a width of a grid line of the grid protective pattern may be greater than a width of a grid line of the metal grid pattern.

According to some embodiments of the present specification, the grid protective pattern may include the same material as a touch insulating layer disposed in the display area.

According to some embodiments of the present specification, the display device may further include a grid protective layer covering the grid protective pattern and disposed on the stress relief layer in the bending area.

According to some embodiments of the present specification, the grid protective layer may include the same material as a touch protective layer disposed in the display area.

According to embodiments of the present specification, there is provided a display device including a substrate including a display area and a bending area, a first organic material layer disposed in the bending area of the substrate, a connection line crossing the bending area of the substrate and disposed on the first organic material layer, a second organic material layer covering the connection line in the bending area, a third organic material layer disposed on the second organic material layer in the bending area, and a metal grid pattern disposed on the connection line in the bending area, in which a groove is disposed in an upper surface of the third organic material layer, and the metal grid pattern is disposed to correspond to the groove.

According to some embodiments of the present specification, the metal grid pattern may have rhombus-shaped openings. According to some embodiments of the present specification, the metal grid pattern may have quadrangular, or hexagonal openings.

According to some embodiments of the present specification, the metal grid pattern may include the same material as a touch electrode or a first bridge electrode disposed in the display area.

According to some embodiments of the present specification, the display device may further include an organic protective layer covering the metal grid pattern and disposed on the third organic material layer in the bending area.

According to some embodiments of the present specification, the display device may further include an inorganic protective pattern overlapping the metal grid pattern and disposed between the organic protective layer and the metal grid pattern in the bending area.

Although the embodiments of the present specification have been described in more detail with reference to the accompanying drawings, the present specification is not necessarily limited to these embodiments, and various modifications may be carried out without departing from the technical spirit of the present specification. Accordingly, the embodiments disclosed in the present specification are not intended to limit the technical spirit of the present specification, but are intended to describe the technical spirit of the present specification and the scope of the technical spirit of the present specification is not limited by these embodiments. Accordingly, it should be understood that the above-described embodiments are illustrative and not restrictive in all aspects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area and a bending area;
a connection line crossing the bending area of the substrate;
a planarization layer covering the connection line in the bending area;
a stress relief layer disposed on the planarization layer in the bending area;
a metal grid pattern disposed on the connection line in the bending area;
a groove in an upper surface of the stress relief layer, wherein the metal grid pattern corresponds to the groove.

2. The display device of claim 1, wherein the metal grid pattern is disposed on the entirety of the bending area.

3. The display device of claim 1, wherein the metal grid pattern has rhombus-shaped openings.

4. The display device of claim 1, wherein the metal grid pattern has quadrangular openings or hexagonal openings disposed in a honeycomb shape.

5. The display device of claim 1, further comprising:
a bank layer disposed in the display area, wherein the stress relief layer includes the same material as the bank layer.

6. The display device of claim 1, further comprising:
a touch electrode disposed in the display area, wherein the metal grid pattern includes the same material as the touch electrode.

7. The display device of claim 1, further comprising a grid protective layer covering the metal grid pattern and disposed on the stress relief layer in the bending area.

8. The display device of claim 7, further comprising:
a touch protective layer disposed in the display area, wherein the grid protective layer includes the same material as the touch protective layer.

9. The display device of claim 1, further comprising:
a first bridge electrode disposed in the display area, wherein the metal grid pattern includes the same material as the first bridge electrode.

10. The display device of claim 1, further comprising a grid protective pattern overlapping the metal grid pattern in the bending area.

11. The display device of claim 10, wherein a width of a grid line of the grid protective pattern is greater than a width of a grid line of the metal grid pattern.

12. The display device of claim 10, further comprising:
a touch insulating layer disposed in the display area, wherein the grid protective pattern includes the same material as the touch insulating layer.

13. The display device of claim 10, further comprising a grid protective layer covering the grid protective pattern and disposed on the stress relief layer in the bending area.

14. The display device of claim 13, further comprising:
a touch protective layer disposed in the display area, wherein the grid protective layer includes the same material as the touch protective layer.

15. A display device comprising:
a substrate including a display area and a bending area;
a first organic material layer disposed in the bending area of the substrate;
a connection line crossing the bending area of the substrate and disposed on the first organic material layer;
a second organic material layer covering the connection line in the bending area;
a third organic material layer disposed on the second organic material layer in the bending area;
a metal grid pattern disposed on the connection line in the bending area;
a groove in an upper surface of the third organic material layer, wherein the metal grid pattern corresponds to the groove.

16. The display device of claim 15, wherein the metal grid pattern has rhombus-shaped openings.

17. The display device of claim 15, wherein the metal grid pattern has quadrangular or hexagonal openings.

18. The display device of claim 15, further comprising:
a touch electrode or a first bridge electrode disposed in the display area, wherein the metal grid pattern includes the same material as the touch electrode or first bridge electrode.

19. The display device of claim 15, further comprising an organic protective layer covering the metal grid pattern and disposed on the third organic material layer in the bending area.

20. The display device of claim 19, further comprising an inorganic protective pattern overlapping the metal grid pattern and disposed between the organic protective layer and the metal grid pattern in the bending area.
